(19) United States
(12) Patent Application Publication
(10) Pub. No.: US 2016/0254425 A1
(43) Pub. Date: Sep. 1, 2016

(54) LED ENCAPSULANT

(71) Applicant: WACKER CHEMIE AG, Munich (DE)

(72) Inventors: Kyuha CHUNG, Seoul (KR); Doo Jin KANG, Uiwang-si (KR); Chang Sic KIM, Cheongwon-gun (KR); Kyung-Hak KIM, Gwangmyeong-si (KR); JiHye PARK, Bucheon-si (KR); YoungJin KIM, Paju-si (KR)

(21) Appl. No.: 15/030,079

(22) PCT Filed: Oct. 24, 2014
(86) PCT No.: PCT/EP2014/072811

§ 371 Date: Apr. 18, 2016

(30) Foreign Application Priority Data
Oct. 24, 2013 (KR) 10-2013-0127331

(51) Int. Cl. H01L 33/56; H01L 33/50

(52) U.S. Cl. CPC H01L 33/56; H01L 33/502; H01L 2933/0091

(57) ABSTRACT

An LED encapsulant comprises a scattering particle mixture, which includes:
(i) a linear polymer including a dimethylsiloxane group which has a vinyl end substituent and/or a linear polymer including a methylphenylsiloxane group which has a vinyl end substituent; and (ii) at least one vinyl-based resin selected from the group consisting of a vinyl-based ViMQ resin. An LED package comprising the encapsulant is also disclosed.

### CROSS REFERENCE TO RELATED APPLICATIONS

This application is the U.S. National Phase of PCT Appln. No. PCT/EP2014/072811 filed Oct. 24, 2014, which claims priority to Korean Application No. 10-2013-0127331 filed Oct. 24, 2013, the disclosures of which are incorporated in their entirety by reference herein.

### BACKGROUND OF THE INVENTION

1. Technical Field

The present invention relates to an LED encapsulant comprising scattering particles which scatter light produced from a light emitting diode (hereinafter, this will be referred to as ‘LED’) chip.

2. Background Art

An LED package is mainly constituted by a chip, an adhesive, an encapsulant, a fluorescent substance and a heat-radiant material.

Among these components, the LED chip is the part that produces light. Light is produced when electric current is applied to a p-n junction possessed by the chip, and electrons combine with positive holes. The adhesive is often used for bonding other materials together in the LED package. The function includes allowing mechanical contact between faces of a chip and a package, a package and a substrate, a substrate and a heat sink or the like; electrical conduction with a substrate or a package; heat release; or the like. The LED fluorescent substance is a typical wavelength conversion substance of a dye, a semiconductor or the like and refers to a substance that absorbs energy of electron beam, X-rays, ultraviolet rays and the like and then emits some of the absorbed energy as visible rays. The fluorescent substance has played an important role in developing an LED package for white light. The heat-radiant material includes a heat sink, a slug and the like, and is closely related to the life of an LED package.

The basic function of the encapsulant is to protect an LED chip and emit light to the outside by allowing penetration of light. As an LED encapsulant resin, epoxy systems and silicone systems are generally used. In recent years, silicone encapsulants have been mostly used for high-power LED packaging materials. As compared to conventional epoxy encapsulants, silicone encapsulants are more durable against blue and ultraviolet rays and also highly resistant to heat and moisture. For this reason, silicone encapsulants are used for lighting LEDs and backlight LEDs nowadays. However, there is a problem in that the gas barrier properties are poor and thus degradation of elements or corrosion of electrodes may be experienced.

Currently used LEDs are configured in the manner that an LED encapsulant covers a blue LED chip and a yellow fluorescent substance (YAG) is dispersed in an LED encapsulant resin. When the blue light from the LED chip passes the yellow fluorescent substance, colour changes to white. The white light obtained in this manner provides high brightness, but there are disadvantages such as that it is difficult to control the hue and there is a phenomenon of changing in colour due to a change in the surrounding temperature. In this type of method, since the colour temperature is controlled by adjusting the amount of a fluorescent substance dispersed in an LED encapsulant resin, the content of the fluorescent substance has to be increased in order to lower the colour temperature. This results in increasing the cost of manufacturing an LED package, and consequently, a technique of reducing the amount of yellow fluorescent substances used is required.

KR20090017346A describes an LED package including diffusion means comprising reflective particles. This publication and US2005006794A1 and EP2105466A1 discloses LED encapsulants comprising scattering particle mixtures comprising vinyl-based MQ-resins.

### SUMMARY OF THE INVENTION

An object of the present invention is to provide an LED encapsulant providing high brightness and efficient control of colour temperature, and an LED package comprising the same. These and other objects are achieved by the present invention, which provides an LED encapsulant comprising a scattering particle mixture, which includes: (i) a linear polymer including a dimethylsiloxane group which has a vinyl end substituent and/or a linear polymer including a methylphenylsiloxane group which has a vinyl end substituent; and (ii) at least one vinyl-based resin selected from the group consisting of a vinyl-based ViMQ resin, a vinyl-based ViT^{ph}QM resin, and a vinyl-based ViT^{H}T^{ph}QM resin which has an Si—H functional group. The invention also pertains to an LED package comprising the encapsulant.

### BRIEF DESCRIPTION OF THE DRAWINGS

FIG. 1 is a graph showing the results of luminous intensity measurement of encapsulants according to Examples 1 to 8 and Comparative Example 1.

FIG. 2 is a graph showing the results of colour temperature (CCT) measurement of encapsulants according to Examples 1 to 8 and Comparative Example 1.

FIG. 3 is a graph showing a graph integration value of encapsulants according to Examples 1 to 8 and Comparative Example 1.

FIG. 4 is a graph showing the results of luminous intensity measurement of encapsulants according to Examples 9 to 16 and Comparative Example 1.

FIG. 5 is a graph showing the results of colour temperature (CCT) measurement of encapsulants according to Examples 9 to 16 and Comparative Example 1.

FIG. 6 is a graph showing a graph integration value of encapsulants according to Examples 9 to 16 and Comparative Example 1.

FIG. 7 is a graph showing the results of luminous intensity measurement of encapsulants according to Examples 17 to 22 and Comparative Examples 2 to 7.

FIG. 8 is a graph showing the results of colour temperature (CCT) measurement of encapsulants according to Examples 17 to 22 and Comparative Examples 2 to 7.

FIG. 9 is a graph showing a colour temperature and luminous intensity value of encapsulants according to Examples 17 to 22 and Comparative Examples 2 to 7.

FIG. 10 is a graph showing the results of luminous intensity measurement of encapsulants according to Examples 23 to 33.

FIG. 11 is a graph showing the results of colour temperature (CCT) measurement of encapsulants according to Examples 23 to 33.

FIG. 12 is a graph showing the results of luminous intensity measurement of encapsulants according to Examples 34 to 39 and Comparative Example 8.

FIG. 13 is a graph showing the results of colour temperature (CCT) measurement of encapsulants according to Examples 34 to 39 and Comparative Example 8.

FIG. 14 is a graph showing the results of luminous intensity measurement of encapsulants according to Examples 17 to 22 and Comparative Examples 9 to 14.

FIG. 15 is a graph showing the results of colour temperature (CCT) measurement of encapsulants according to Examples 17 to 22 and Comparative Examples 9 to 14.

### DETAILED DESCRIPTION OF THE PREFERRED EMBODIMENTS

According to the present invention, in a package that converts blue light emitted by an LED chip to white light by using a yellow fluorescent substance, high luminous efficiency is provided and the colour temperature is efficiently controlled. In addition, the equal colour temperature is obtained without lowering the luminous efficiency even if the amount of a yellow fluorescent substance used is reduced.

The present invention will be described in more detail below.

### Silicone Matrix and Scattering Particles

The invention relates to a LED encapsulant comprising a scattering particle mixture, comprising:
(i) a linear polymer including a dimethylsiloxane group which has at least one vinyl end substituent and/or a linear polymer including a methylphenylsiloxane group and/or a diphenylsiloxane group which has at least one vinyl end substituent; and
(ii) at least one resins selected from MQ resin, MDT resin or MT resin, comprising a Si—H Si—Vi and Si-Aryl functional groups. The above mentioned resin has preferably following structures M^{Vi}D^{H}D^{Ph}, M^{Vi}M^{H}D^{Ph}T^{Ph}, M^{Vi}D^{H}T^{Ph}, M^{Vi}M^{H}T^{Ph}, or M^{Vi}(D)T^{Ph}.

An LED encapsulant includes a basic silicone matrix and scattering particles which do not mix with each other. In one embodiment of this invention (i) acts as silicone matrix and (ii) as scattering particles. In a second embodiment of this invention (ii) acts as silicone matrix and (i) as scattering particles. Herein, the basic silicone matrix can be largely divided into a methylsiloxane matrix and a phenylsiloxane matrix.

When the basic silicone matrix is a methylsiloxane matrix, (i) a linear polymer ((—(CH₃)₂SiO)ₙ—) including a dimethylsiloxane group which has a vinyl end substituent and/or (ii) a vinyl-based ViMQ resin is/are used as the basic silicone matrix. A substance that does not mix with the methylsiloxane matrix is used as scattering particles, such as one or more of (i) a linear polymer (—((CH₃)(Ph)SiO)ₙ—) including a methylphenylsiloxane group which has a vinyl end substituent, (ii) a linear polymer (—((Ph)₂SiO)ₙ—) including a diphenylsiloxane group which has a vinyl end substituent, (iii) a MDT resin or MT resin, which has desirably M^{Vi}D^{H}D^{Ph}T^{Ph}, M^{Vi}M^{H}D^{Ph}T^{Ph}, M^{Vi}D^{H}T^{Ph}, M^{Vi}M^{H}T^{Ph}, or M^{Vi}(D)T^{Ph} structure, and a vinyl-based resin which has an Si—H functional group and aryl functional group in which hydrogen crosslinking is possible are used.

When the basic silicone matrix is a phenylsiloxane matrix, one or more of (i) a linear polymer (—(((CH₃)(Ph)SiO)ₙ)—) including a methylphenylsiloxane group which has a vinyl end substituent, (ii) a linear polymer ((Ph)₂SiO)ₙ including a diphenylsiloxane group which has a vinyl end substituent, (iii) a MDT resin or MT resin, which has desirably M^{Vi}D^{H}D^{Ph}T^{Ph}, M^{Vi}M^{H}D^{Ph}T^{Ph}, M^{Vi}D^{H}T^{Ph}, M^{Vi}M^{H}T^{Ph}, or M^{Vi}(D)T^{Ph} structure, and a vinyl-based resin which has an Si—H functional group and aryl functional group as the basic silicone matrix. In addition, when the basic silicone matrix is a phenylsiloxane matrix, a substance that does not mix with the phenylsiloxane matrix is used as scattering particles, such as (i) a linear polymer (((CH₃)₂SiO)ₙ) including a dimethylsiloxane group which has a vinyl end substituent and/or (ii) a vinyl-based ViMQ resin are/is used.

The content of scattering particles is controlled according to the vinyl base resin, linear polymer, surfactant and/or other additives which are used. As the content of scattering particles increases, light loss would be expected to increase. Thus, the content of scattering particles should be controlled for optimized light scattering. As scattering particles, liquid type or solid type scattering particles are used. Liquid type scattering particles are better to control optical properties, but solid type scattering particles are better for stability and lower viscosity.

The linear polymer may be a linear polymer (((CH₃)₂SiO)ₙ) including a dimethylsiloxane group which has a vinyl end substituent. Since the vinyl polymer has a methyl group, high heat resistance is exhibited. For example, the heat resistance for yellowing stability is exhibited up to about 150° C.

In addition, a linear polymer including a methylphenylsiloxane group which has a vinyl end substituent or a linear polymer including a diphenylsiloxane group which has a vinyl end substituent may also be used. These polymers exhibit excellent gas barrier properties.

As a vinyl-based resin, a vinyl-based ViMQ resin, a MDT resin or MT resin, which has desirably M^{Vi}D^{H}D^{Ph}T^{Ph}, M^{Vi}M^{H}D^{Ph}T^{Ph}, M^{Vi}D^{H}T^{Ph}, M^{Vi}M^{H}T^{Ph}, or M^{Vi}(D)T^{Ph} structure, and a vinyl-based resin which has an Si—H functional group and aryl functional group

Abbreviations used in the text:
M=Monofunctional structural silicone-units),
D=Difunctional structural silicone-units,
T=Trifunctional structural silicone-units, and
Q=Tetrafunctional structural silicone-units,
are known from textbooks and exemplary shown by Chemical Formula 1 below.

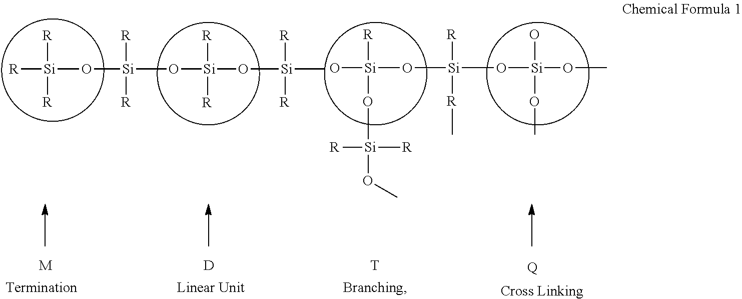

In the text which follows, H-Hydrogen, Ph=Phenyl, and Vi-Vinyl.

### Surfactant

An LED encapsulant may further include a surfactant having a (CH₃)₂Si—O structure and a (CH₃)PhSi—O structure, in addition to the scattering particle mixture. The surfactant corresponds to a stabilizer for scattering particle dispersion. When a part having the (CH₃)₂Si—O structure is given as A and a part having the (CH₃)PhSi—O structure is given as B, the surfactant has any one structure of ABA, BAB and AB.

Examples include ((CH₃)(Ph)SiO)ₙ—((CH₃)₂SiO)ₘ, ((CH₃)(Ph)SiO)ₙ—((CH₃)₂SiO)ₘ—((CH₃)(Ph)SiO)ₙ, and ((CH₃)₂SiO)ₘ—((CH₃)(Ph)SiO)ₙ—((CH₃)₂SiO)ₘ.

Vinyltrimethoxysilane, methacryloxymethylmethyldimethoxysilane, methacryloxymethyltriethoxysilane, 3-methacryloxypropyltrimethoxysilane, methyltriethoxysilane, allyltriethoxysilane, octyltriethoxysilane, tetraethoxysilane, or the like may be used as the surfactant.

The content of scattering particles is 5 to 20 wt % based on the total weight of the scattering particle mixture.

In addition, at least one particulate selected from TiO₂, ZnO and silica may be additionally added. The sum of contents of TiO2, ZnO and silica is 0.05 to wt % based on the total content of the scattering particle mixture. The average particle size of TiO₂, ZnO and silica is between 1 and 50 nm.

### Hydrogen Crosslinker

Examples of hydrogen crosslinkers include (CH₃)₃Si((CH₃)HSiO)ₓ((CH₃)₂SiO)_{y}Si(CH₃)₃, where 5≦x≦50 and 5≦y≦100.

### Ingredients

Ethynylcyclohexanol (ECH) or the like may be used as a curing inhibitor for controlling a curing rate. As a catalyst, for example, a platinum catalyst, and as a fluorescent substance, YAG or the like may be used. Moreover, nanoparticles may also be included.

The present invention provides an LED package comprising the LED encapsulant described above. Herein, the LED chip preferably emits blue light when electric current is applied. In addition, preferably, a yellow fluorescent substance is additionally included. The LED package is prepared by encapsulating an LED chip that emits blue light when electric current is applied, with the LED encapsulant obtained by mixing a yellow fluorescent substance.

### EXAMPLES

Vinyl resin A as (M^{Vi}D^{H}D^{Ph}T^{Ph}) which has an Si—H functional group and aryl substitutent groups, liquid type scattering particles B-1 (viscosity: 1000 cps, molecular weight: 16500 g/mol, dimethylpolysiloxane having a vinyl end substituent), surfactant M 15%, and as an inhibitor ECH (Ethynylcyclehexanol) 0.01% were mixed in the respective amount shown in Table 1.

Herein, the surfactant M may have a [H(CH₃)₂Si(OSi(CH₃)₂)ₐ(CH₃)₂Si](CH₂)₂[Si(CH₃)₂((CH₃)(C₆H₅)SiO)_{b}(OSi(CH₃)₂)_{c}Si(CH₃(CH₂)₂[(CH₃)₂Si(OSi(CH₃)₂)ₐ(CH₃)₂SiH] structure. In this case, M2 to M6 are as follows:

M2: a=15, b=60, C=12

M3: a=60, b=60, c=12

M5: a=220, b=60, c=12

M6: a=7, b=60, c=12.

The surfactant M may also have a [(C₂H₂)(CH₃)₂Si((CH₃)(C₆H₅)SiO)ₐ(OSi(CH₃)₂)_{b}(CH₃)₂Si](CH₂)₂[Si(CH₃)₂(OSi(CH₃)₂)_{c}(CH₃)₂Si]_{y}(CH₂)₂[(CH₃)₂Si((CH₃)(C₆H₅)SiO)ₐ(OSi(CH₃)₂)_{b}(CH₃)₂Si(C₂H₂)] structure. In this case, M7, M8, M12, M14, M15, M16, and M18 are as follows:

M7: a=60, b=12, C=60

M8: a=60, b=12, c=220

M12: a=60, b=12, c=7

M14: a=60, b=12, c=15

M15: a=22, b=12, C=7

M16: a=22, b=12, c=15

M17: a=22, b=12, c=60

M18: a=22, b=12, c=220.

The surfactant M may also have a [H(CH₃)₂Si(OSi(CH₃)₂)ₐ(CH₃)₂Si](CH₂)₂[(CH₃)₂Si((CH₃)(C₆H₅)SiO)_{b}(OSi(CH₃)₂)_{c}(CH₃)₂Si(C₂H₂)] structure. In this case, M9: a=7, b=60 and c=12.

The surfactant M may also have a [(OCH₃)₃Si](CH₂)₂[Si(CH₃)₂(OSi(CH₃)₂)ₐ(CH₃)₂Si](CH₂)₂[(OCH₃)₃Si] structure. In this case M4: a=60.

The surfactant M may also have a [(OCH₃)₃Si](CH₂)₂[Si(CH₃)₂(O(CH₃)(C₆H₅)Si)ₐ(OSi(CH₃)₂)_{b}OSi(CH₃)₂ (C₂H₂)] structure. In this case, M13: a=60, b=12.

The surfactant M may also have a [H(CH₃)₂Si(OSi(CH₃)₂)ₐ(CH₃)₂Si](CH₂)₂[(OCH₃)₃Si] structure. In this case, M4: a=15.

The surfactant M may also have a [(C₆H₁₃)₃Si](CH₂)₂[Si(CH₃)₂((CH₃)(C₆H₅)SiO)ₐ(OSi(CH₃)₂)_{b}(CH₃)₂Si](CH₂)₂[Si(CH₃)₂(OSi(CH₃)₂)_{c}(CH₃)₂Si](CH₂)₂[(CH₃)₂Si((CH₃)(C₆H₅)SiO)ₐ(OSi(CH₃)₂)_{b}(CH₃)₂Si](CH₂)₂[(C₆H₁₃)₃Si] structure. In this case, ML2: a=60, b=12, c=60 and ML3: a=60, b=12, c=15.

Scattering particles and the surfactant M18 were dispersed using a mixer.

Ethynylcyclohexanol (ECH) was then added in an amount of 0.01 wt % as a curing inhibitor, and then mixed using a speed mixer (2000 rpm/1 minute).

A Pt catalyst (Platinum(O)-1,3-divinyl-1,1,3,3-tetramethyl-disiloxane complex) was added in an amount of 1 ppm, and then mixed using a speed mixer (2000 rpm/1 minute).

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

As a fluorescent substance, a yellow phosphor which has an excited wavelength in the 540˜570 nm range and red phosphor which has an excited wavelength in the 630˜670 nm range, were added in an amount of proper parts by weight with respect to 100 parts by weight of the total sample (Table 1), and then thoroughly mixed. In this case, target colour coordination is x=0.3, y=0.275.

TABLE 1

| | | Total | Ratio of |
|---|---|---|---|
| | B-1 | Phosphor | Yellow:RED |
| Comparative | | 7.00 part | 95:05 |
| Example 1 | | | |
| Example 1 | 0.50% | 6.50% | 95:05 |
| Example 2 | 0.75% | 6.50% | 99:01 |
| Example 3 | 1.00% | 6.50% | 97:03 |
| Example 4 | 1.25% | 6.50% | 95:05 |
| Example 5 | 1.50% | 6.50% | 95:05 |
| Example 6 | 1.75% | 6.50% | 95:05 |
| Example 7 | 2.00% | 6.50% | 95:05 |
| Example 8 | 2.25% | 6.25% | 95:05 |
| Example 9 | 2.50% | 6.25% | 95:05 |
| Example 10 | 2.75% | 6.25% | 95:05 |
| Example 11 | 3.00% | 6.25% | 95:05 |

### Comparative Example

An encapsulant was prepared in the same manner as in Examples 1 to 11, except that OE6631 (Dow Corning) was used in place of the vinyl resin A, B-1, and surfactant M which were used in the Examples.

Yellow and red phosphor mixture was added in an amount of 7 parts by weight with respect to 100 parts by weight of the total sample, and then, the composition was thoroughly mixed.

### Examples 12 to 16

Vinyl resin A as (M^{Vi}D^{H}D^{Ph}T^{Ph}) which has an Si—H functional group and aryl functional group, solid type scattering particle B-2(Zinc Oxide) and surfactant M18 15% were mixed in the respective amount shown in Table 2 below.

Scattering particles and the surfactant M18 15% were dispersed using a mixer.

Ethynylcyclohexanol (ECH) 0.01% was added in an amount of 0.16 wt % as a curing inhibitor, and then mixed using a mixer.

A Pt catalyst (Platinum(O)-1,3-divinyl-1,1,3,3-tetramethyl-disiloxane complex) was added in an amount of 1 ppm, and then mixed using a mixer.

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

As a fluorescent substance, yellow phosphor which having excited wavelengths at 540˜570 nm and red phosphor having excited wavelength at 630˜670 nm, were added in an amount of proper parts by weight with respect to 100 parts by weight of the total sample, and then it was thoroughly mixed. In this case, target colour coordination is x=0.45, y=0.41.

TABLE 2

| | B-2 |
|---|---|
| Example 12 | 0.0 |
| Example 13 | 1.0 |
| Example 14 | 2.0 |
| Example 15 | 3.0 |
| Example 16 | 4.0 |

### Examples 17 to 21

Vinyl resin-A, as MDT or MT resin which has an Si—H functional group and aryl functional group, Liquid type scattering particles B-1 (viscosity: 1000 cps, molecular weight: 16500 g/mol, dimethylpolysiloxane having a vinyl end substituent), surfactant M 15%, and as an inhibitor ECH (Ethynylcyclehexanol) 0.01% were mixed.

Scattering particles B-1 7% and various surfactant Ms 15% were dispersed using a mixer in the respective amount shown in Table 3.

Ethynylcyclohexanol (ECH) was added in an amount of 0.01 wt % as a curing inhibitor, and then mixed using a mixer.

A Pt catalyst (Platinum(O)-1,3-divinyl-1,1,3,3-tetramethyl-disiloxane complex) was added in an amount of 1 ppm, and then mixed using a mixer.

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

Yellow phosphor having excited wavelengths at 540˜570 nm and red phosphor having excited wavenlengths at 630˜670 nm, were added in an amount of proper parts by weight with respect to 100 parts by weight of the total sample, and then thoroughly mixed. In this case, target colour coordination is x=0.45, y=0.41.

TABLE 3

| | Surfactant M | B-1 |
|---|---|---|
| Example 17 | M12 15% | 7% |
| Example 18 | M6 15% | 7% |
| Example 19 | M11 15% | 7% |
| Example 20 | M18 15% | 7% |
| Example 21 | ML3 15% | 7% |

### Comparative Example 2

Each encapsulant was prepared in the same manner as in Examples 17 to 21, except that OE6631 (Dow Corning) was used in place of the vinyl resin-A, B-1 and surfactant M which were used in the Examples.

### Examples 22 to 23

Vinyl resin-A, as MDT or MT resin which has an Si—H functional group and aryl functional group, Liquid type scattering particles B-1 (viscosity: 1000 cps, molecular weight: 16500 g/mol, dimethylpolysiloxane having a vinyl end substituent), surfactant M 15%, and as an inhibitor ECH (Ethynylcyclehexanol) 0.01% were mixed. In case of example 22, Inhibitor ECH was not used to compare light efficiency according to curing speed.

Scattering particles B-1 and the surfactant M5 were dispersed using mixer.

Ethynylcyclohexanol (ECH) was added in an amount of 0.01 wt % as a curing inhibitor, and then mixed using a mixer.

A Pt catalyst (Platinum(O)-1,3-divinyl-1,1,3,3-tetramethyl-disiloxane complex solution) was added in an amount of 1 ppm, and then mixed using a mixer.

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

Yellow phosphor having excited wavelengths at 540˜570 nm and red phosphor having excited wavelengths at 630˜670 nm, were added in an amount of proper parts by weight with respect to 100 parts by weight of the total sample, and then thoroughly mixed. In this case, target colour coordination is x=0.45, y=0.41.

TABLE 4

| | Surfactant | | Inhibitor |
|---|---|---|---|
| 0 | M18 | B-1 | ECH |
| Example 22 | 15% | 5% | ◯ |
| Example 23 | 15% | 5% | X |
| Comparative | | | |
| Example 3 | | | |

### Comparative Example 3

Each encapsulant was prepared in the same manner as in Examples 22 to 23, except that OE6631 (Dow Corning) was used in place of the vinyl resin-A, B-1 and surfactant M which were used in the Examples.

### Examples 24 to 25

Vinyl resin-A, as MDT or MT resin which has an Si—H functional group and aryl functional group, Liquid type scattering particles B-1 (viscosity: 1000 cps, molecular weight: 16500 g/mol, dimethylpolysiloxane having a vinyl end substituent), surfactant M18 15%, and as an inhibitor ECH (Ethynylcyclehexanol) 0.01% were mixed. In case of example 22, Inhibitor ECH was not used to compare light efficiency according to curing speed.

Scattering particles B-1 and the surfactant M18 were dispersed using mixer.

Ethynylcyclohexanol (ECH) was added in an amount of 0.01 wt % as a curing inhibitor, and then mixed using a mixer.

A Pt catalyst (Platinum(O)-1,3-divinyl-1,1,3,3-tetramethyl-disiloxane complex solution) was added in an amount of 1 ppm, and then mixed using a mixer.

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

Yellow phosphor having excited wavelengths at 540˜570 nm and red phosphor having excited wavelengths at 630˜670 nm, were added in an amount of proper parts by weight with respect to 100 parts by weight of the total sample, and then thoroughly mixed. Target colour coordination of example 24 is x=0.45, y=0.41 and example 25 is X=0.30, y=0.28.

TABLE 5

| | Surfactant | | | |
|---|---|---|---|---|
| | M18 | B-1 | CIE X | CIE Y |
| Comparative | | | 0.448 | 0.411 |
| Example 4 | | | | |
| Example 24 | 15% | 2% | 0.451 | 0.411 |
| Comparative | | | 0.3040 | 0.2818 |
| Example 5 | | | | |
| Example 25 | 15% | 2% | 0.3027 | 0.2829 |

### Comparative Example 4

Each encapsulant was prepared in the same manner as in Examples 24 for colour coordination x=0.45, y=0.41, except that OE6631 (Dow Corning) was used in place of the vinyl resin-A, B-1 and surfactant M which were used in the Examples.

### Comparative Example 5

Each encapsulant was prepared in the same manner as in Examples 25 for colour coordination x=0.30, y=0.28, except that OE6631 (Dow Corning) was used in place of the vinyl resin-A, B-1 and surfactant M which were used in the Examples.

### Examples 26 to 33

Vinyl resin-A, as MDT or MT resin which has an Si—H functional group and aryl functional group, Liquid type scattering particles B-1 (viscosity: 1000 cps, molecular weight: 16500 g/mol, dimethylpolysiloxane having a vinyl end substituent), surfactant M18, and as an inhibitor ECH (Ethynylcyclehexanol) 0.01% were mixed.

Scattering particles B-1 and the surfactant M18 were dispersed using mixer. Surfactant M18 was mixed as proper amount which is shown in Table 6.

Ethynylcyclohexanol (ECH) was added in an amount of 0.01 wt % as a curing inhibitor, and then mixed using a mixer.

A Pt catalyst (Platinum(O)-1,3-divinyl-1,1,3,3-tetramethyl-disiloxane complex solution) was added in an amount of 1 ppm, and then mixed using a mixer.

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

Yellow phosphor having excited wavelengths at 540˜570 nm and red phosphor having excited wavelength at 630˜670 nm range, were added in an amount of proper parts by weight with respect to 100 parts by weight of the total sample, and then thoroughly mixed. Target colour coordination of example 26˜33 is x=0.45, y=0.41 and example 25 is X=0.45, y=0.41.

### Comparative Example 6

Each encapsulant was prepared in the same manner as in Examples 26˜33, except that OE6631 (Dow Corning) was used in place of the vinyl resin-A, B-1 and surfactant M which were used in the Examples.

TABLE 6

| | Surfactant | |
|---|---|---|
| | M18 | B-1 |
| Comparative | | |
| Example 6 | | |
| Example 26 | 0.0% | 6.50% |
| Example 27 | 5.0% | 6.50% |
| Example 28 | 10.0% | 6.50% |
| Example 29 | 13.0% | 6.50% |
| Example 30 | 15.0% | 6.50% |
| Example 31 | 17.0% | 6.50% |
| Example 32 | 20.0% | 6.50% |
| Example 33 | 25.0% | 6.50% |

### Examples 34 to 40

Vinyl resin-A, as MDT or MT resin which has an Si—H functional group and aryl functional group, Liquid type scattering particles B-1 (viscosity: 1000 cps, molecular weight: 16500 g/mol, dimethylpolysiloxane having a vinyl end substituent), surfactant M18 15%, and as an inhibitor ECH (Ethynylcyclehexanol) 0.01% were mixed.

Scattering particles B-1 and the surfactant M18 15% were dispersed using mixer.

Ethynylcyclohexanol (ECH) was added in an amount of 0.01 wt % as a curing inhibitor, and then mixed using a mixer.

A Pt catalyst (Platinum(O)-1,3-divinyl-1,1,3,3-tetramethyl-disiloxane complex solution) was added in an amount of 1 ppm, and then mixed using a mixer.

A hydrogen crosslinker D (viscosity: 50 cps, molecular weight: 2800 g/mol, linear dimethyl-methylhydride polysiloxane which has a methyl end substituent, (CH₃)₃Si((CH₃) HSiO)ₓ((CH₃)₂SiO)_{y}SI(CH₃)₃, x=10, y=35) was added in the manner that the total ratio of H/Vi ratio=1.2, and then mixed using a mixer.

Yellow phosphor having excited wavelengths at 540˜570 nm range and red phosphor having excited wavelengths at 630˜670 nm range, were added in an amount of proper parts by weight with respect to 100 parts by weight of the total sample, and then thoroughly mixed. Target colour coordination of example 34˜40 is x=0.45, y=0.41.

### Comparative Example 7

Each encapsulant was prepared in the same manner as in Examples 34˜40, except that OE6631 (Dow Corning) was used in place of the vinyl resin-A, B-1 and surfactant M which were used in the Examples.

TABLE 7

| | |
|---|---|
| Surfactant | Phosphor |

| | M18 | B-1 | Yellow | RED |
|---|---|---|---|---|
| Example 34 | 15% | 0% | 18.00 | 4.50 |
| Example 35 | 15% | 1% | 17.60 | 4.40 |
| Example 36 | 15% | 2% | 16.40 | 4.10 |
| Example 37 | 15% | 3% | 15.60 | 3.90 |
| Example 38 | 15% | 4% | 14.80 | 3.70 |
| Example 39 | 15% | 5% | 14.00 | 3.50 |
| Example 40 | 15% | 7% | 14.00 | 3.50 |
| Comparative | | | 22.95 | 4.05 |
| Example 7 | | | | |

### Test Example

### Luminous Flux Comparison According to Amount of Light Scattering Particle B-1

An LED chip was covered with each LED encapsulant prepared in Examples 1 to 11 and Comparative Example 1 using a dispenser.

Curing was performed in an oven.

The above test procedure was repeated using at least one LED chip.

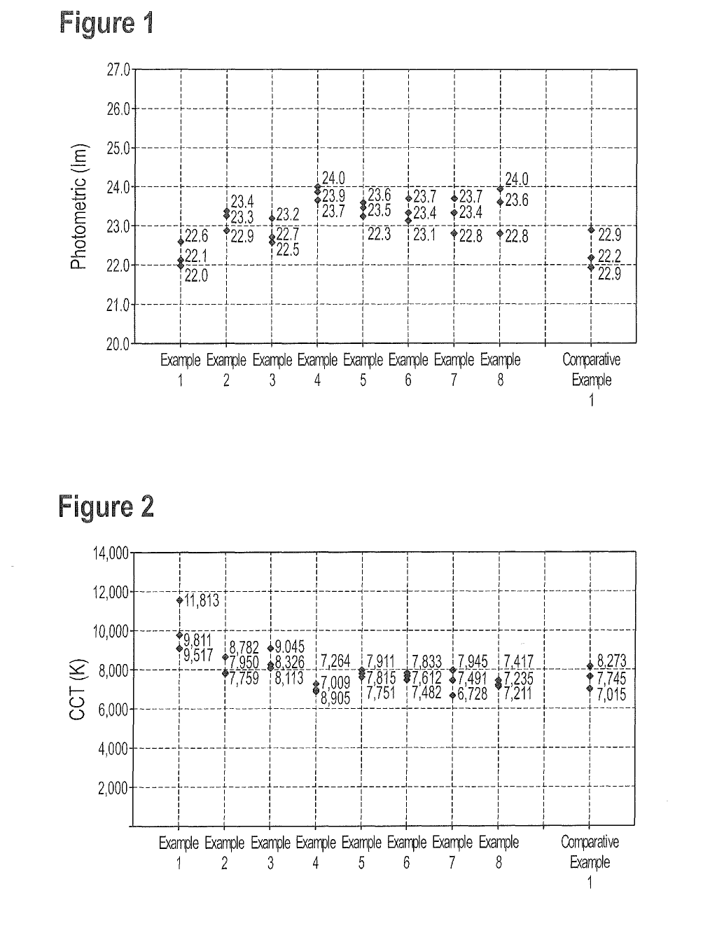

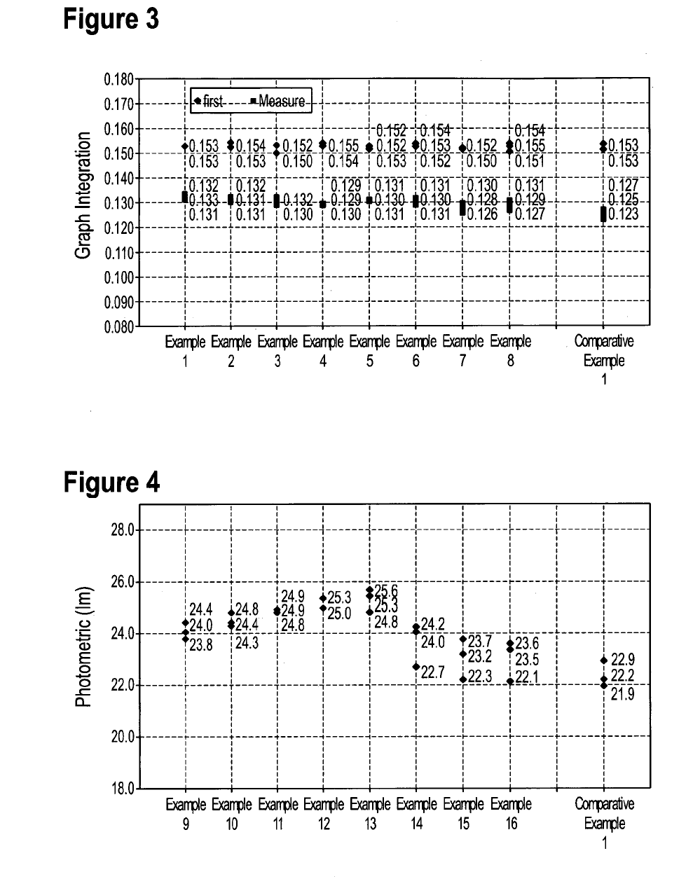

The luminous intensity, CCT value, graph integration initial and final values of the encapsulants were measured, and the results are shown in Table 8 and FIG. 1 below.

TABLE 8

| | B-1 | Phosphor | | Luminous |
|---|---|---|---|---|
| | contents | content | Yellow:RED | flux [lm] |
| Comparative | | 7.00% | 95:05 | 19.89 |
| Example 1 | | | | |
| Example 1 | 0.50% | 6.50% | 95:05 | 20.55 |
| Example 2 | 0.75% | 6.50% | 99:01 | 20.93 |
| Example 3 | 1.00% | 6.50% | 97:03 | 20.67 |
| Example 4 | 1.25% | 6.50% | 95:05 | 20.73 |
| Example 5 | 1.50% | 6.50% | 95:05 | 20.28 |
| Example 6 | 1.75% | 6.50% | 95:05 | 20.44 |
| Example 7 | 2.00% | 6.50% | 95:05 | 20.95 |
| Example 8 | 2.25% | 6.25% | 95:05 | 20.29 |
| Example 9 | 2.50% | 6.25% | 95:05 | 19.51 |
| Example 10 | 2.75% | 6.25% | 95:05 | 19.65 |
| Example 11 | 3.00% | 6.25% | 95:05 | 19.57 |

### Test Example 2

### Luminous Flux Comparison According to Amount of Light Scattering Particle B-2

An LED chip was covered with each LED encapsulant prepared in Examples 12 to 16 and Comparative Example 1 using a dispenser.

Curing was performed in an oven.

The above test procedure was repeated using at least one LED chip.

The luminous intensity, CCT value, graph integration initial and final values of the encapsulants were measured, and the results are shown in Table 9 below and FIG. 2.

TABLE 9

| | | Luminous |
|---|---|---|
| | B-2 | flux [lm] |
| Example 12 | 0.0 | 21.11 |
| Example 13 | 1.0 | 23.37 |
| Example 14 | 2.0 | 24.53 |
| Example 15 | 3.0 | 18.80 |
| Example 16 | 4.0 | 16.29 |

### Test Example 3

### Luminous Flux Comparison According to Different Surfactant

An LED chip was covered with each LED encapsulant prepared in Examples 17 to 21 and Comparative Examples 1 using dispenser.

Curing was performed in an oven.

The above test procedure was repeated using at least one LED chip.

The luminous intensity, CCT value, graph integration initial and final values of the encapsulants were measured, and the results are shown in Table 10 below.

TABLE 10

| | | | Luminous |
|---|---|---|---|
| | Surfactant M | B-1 | flux [lm] |
| Example 17 | M12 1% | 7% | 23.3 |
| Example 18 | M6 1% | 7% | 23.3 |
| Example 19 | M11 1% | 7% | 23.5 |
| Example 20 | M181% | 7% | 24.2 |
| Example 21 | ML3 1% | 7% | 22.2 |
| Comparative | | | 23.8 |
| Example 2 | | | |

### Test Example 4

An LED chip was covered with each LED encapsulant prepared in Examples 22 to 23 and Comparative Examples 1 using dispenser.

Curing was performed in an oven.

The above test procedure was repeated using at least one LED chip.

The luminous intensity, CCT value, graph integration initial and final values of the encapsulants were measured, and the results are shown in Table 11 below.

TABLE 11

| | Surfactant | | | Luminous |
|---|---|---|---|---|
| | M18 | B-1 | Inhibitor | flux [lm] |
| Example 22 | 15% | 5% | ◯ | 19.49 |
| Example 23 | 15% | 5% | X | 18.33 |
| Comparative | | | | 19.18 |
| Example 3 | | | | |

### Test Example 5

An LED chip was covered with each LED encapsulant prepared in Examples 24 to 25 and Comparative Examples 1 using dispenser.

Curing was performed in an oven.

The above test procedure was repeated using at least one LED chip.

The luminous intensity, CCT value, graph integration initial and final values of the encapsulants were measured, and the results are shown in Table 12 below.

TABLE 12

| | Surfactant | | | | Luminous |
|---|---|---|---|---|---|
| | M18 | B-1 | CIE X | CIE Y | flux [lm] |
| Comparative | | | 0.448 | 0.411 | 19.33 |
| Example 4 | | | | | |
| Example 24 | 15% | 2% | 0.451 | 0.411 | 19.13 |
| Comparative | | | 0.3040 | 0.2818 | 20.08 |
| Example 5 | | | | | |
| Example 25 | 15% | 2% | 0.3027 | 0.2829 | 20.31 |

### Test Example 6

An LED chip was covered with each LED encapsulant prepared in Examples 26 to 33 and Comparative Examples 1 using dispenser.

Curing was performed in an oven.

The above test procedure was repeated using at least one LED chip.

The luminous intensity, CCT value, graph integration initial and final values of the encapsulants were measured, and the results are shown in Table 13 below and FIG. 4.

TABLE 13

| | Surfactant | | | Radiometric | Radiometric |
|---|---|---|---|---|---|
| | M18 | B-1 | AVEΔ | B | A |
| Example 26 | 0% | 5% | 0.0077 | 0.08514 | 0.07724 |
| | | | | 0.08689 | 0.07947 |
| Example 27 | 5% | 5% | 0.0069 | 0.08473 | 0.07782 |
| Example 28 | 10% | 5% | 0.0064 | 0.08566 | 0.07774 |
| | | | | 0.08511 | 0.08014 |
| Example 29 | 13% | 5% | 0.0046 | 0.08706 | 0.08208 |
| | | | | 0.08847 | 0.08371 |
| | | | | 0.08825 | 0.08415 |
| Example 30 | 15% | 5% | 0.0021 | 0.08514 | 0.08328 |
| | | | | 0.08484 | 0.08303 |
| | | | | 0.08554 | 0.08284 |
| | | | | 0.08414 | 0.08233 |
| | | | | 0.08606 | 0.08381 |
| Example 31 | 17% | 5% | 0.0034 | 0.08582 | 0.08226 |
| | | | | 0.08702 | 0.08371 |
| | | | | 0.08794 | 0.08447 |
| Example 32 | 20% | 5% | 0.0030 | 0.08624 | 0.08288 |
| | | | | 0.08472 | 0.08197 |
| Example 33 | 25% | 5% | 0.0048 | 0.08863 | 0.08410 |
| | | | | 0.08759 | 0.08351 |
| | | | | 0.08714 | 0.08146 |
| Comparative | | | 0.0067 | 0.08466 | 0.07870 |
| Example 6 | | | | 0.08659 | 0.07938 |
| | | | | 0.08474 | 0.07787 |

### Test Example 7

An LED chip was covered with each LED encapsulant prepared in Examples 34 to 40 and Comparative Examples 1 using dispenser.

Curing was performed in an oven.

The above test procedure was repeated using at least one LED chip.

The luminous intensity, CCT value, graph integration initial and final values of the encapsulants were measured, and the results are shown in Table 13 below and FIG. 4.

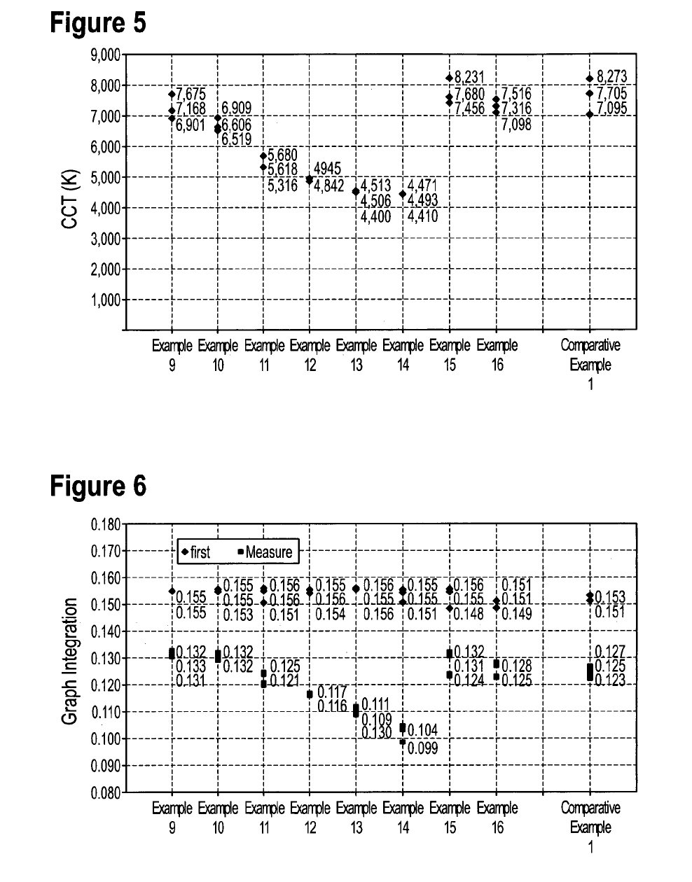

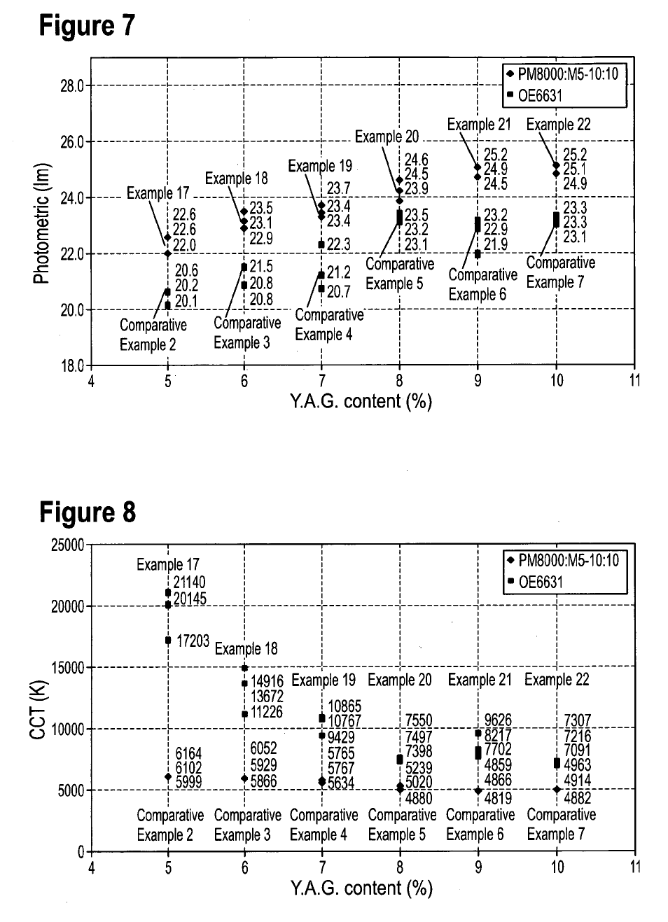

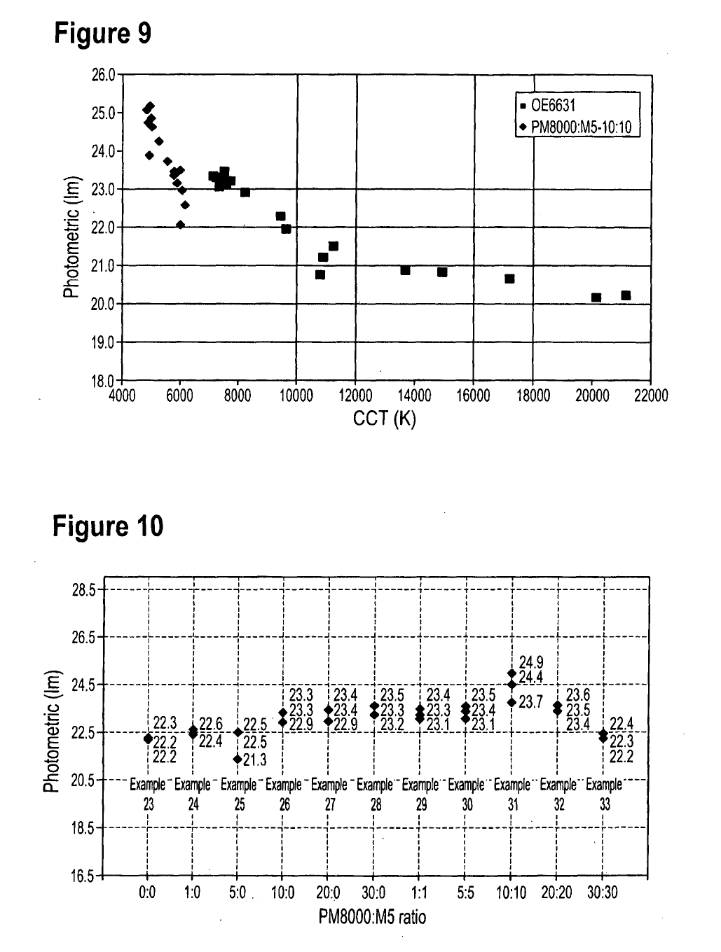

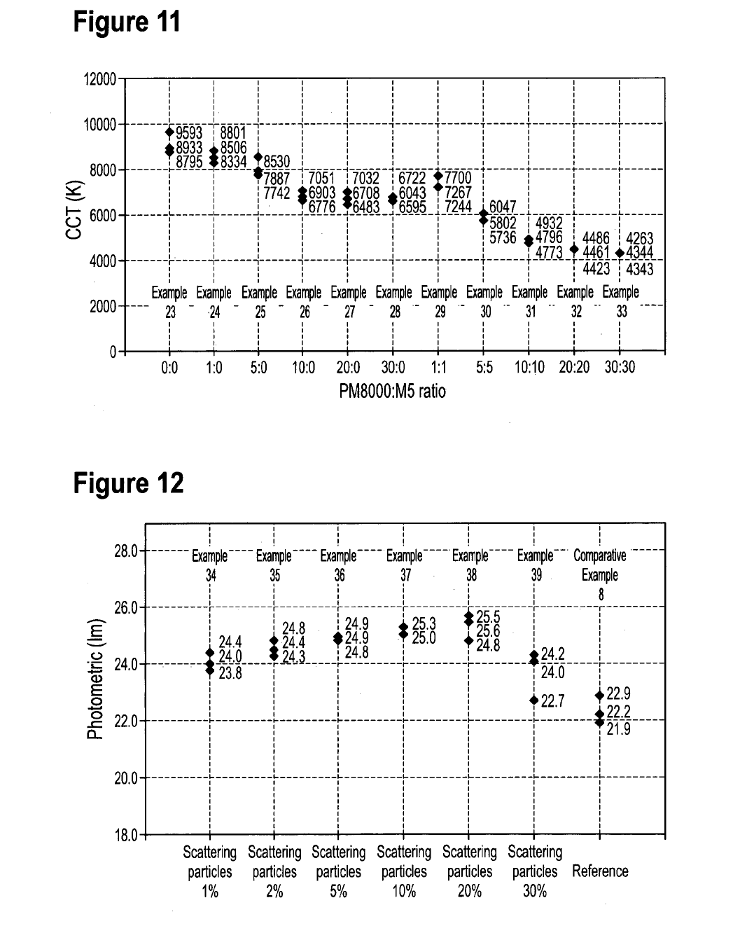

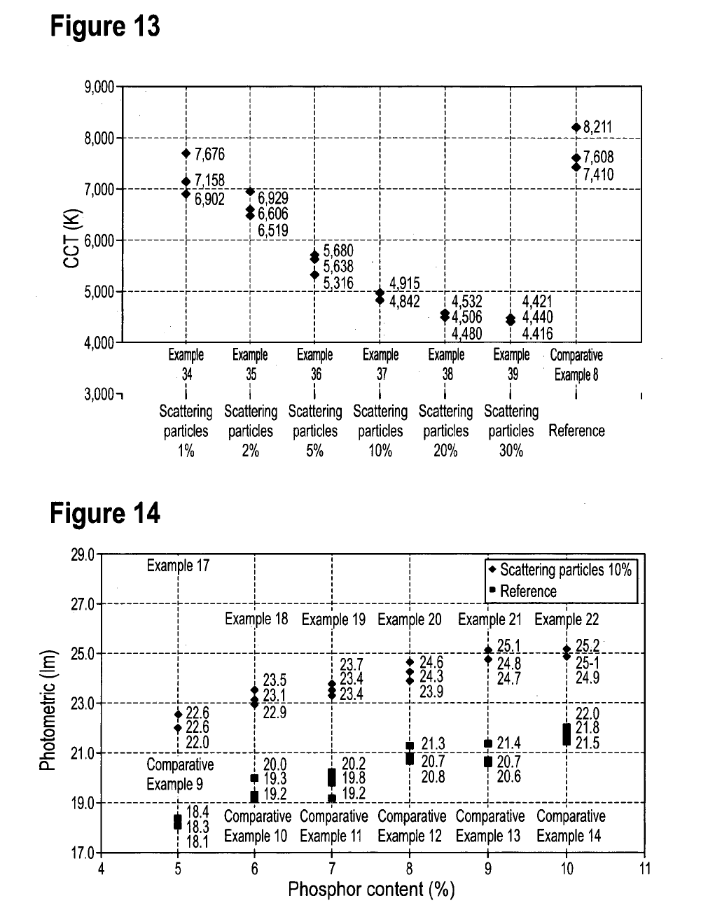

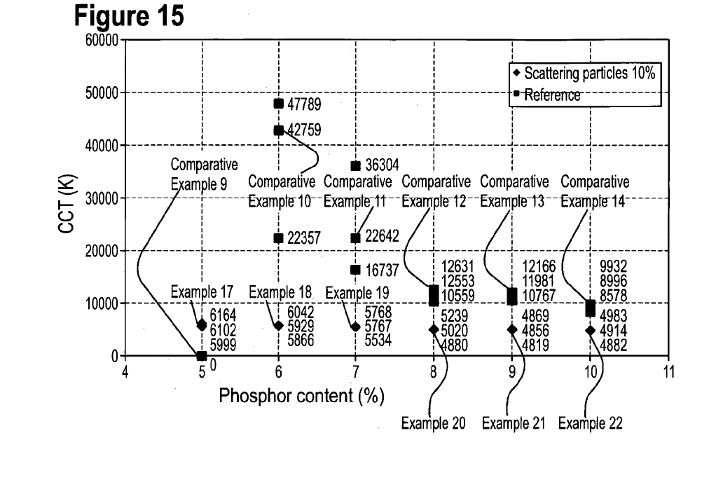

For target colour coordination x=0.45, y=0.41, used amount of yellow phosphor which has excited wavelengths at 540˜570 nm range and red phosphor which has excited wavelengths at 630˜670 nm range, and measured CCT value are shown in Table 14, FIGS. 5, 6 and 7.

When it is compared with Comparative Example 7, it is evident that the required amount of both yellow and red phosphor material can be decreased.

TABLE 14

| | | | Phosphor | | | |
|---|---|---|---|---|---|---|
| | | | contents | | CIE | |
| | | B-1 | Yellow | RED | X | Y |
| Example 34 | 15% | 0% | 18.00 | 4.50 | 0.4520 | 0.4062 |
| | | | | | 0.4544 | 0.4077 |
| | | | | | 0.4544 | 0.4077 |
| Example 35 | 15% | 1% | 17.60 | 4.40 | 0.4600 | 0.4109 |
| | | | | | 0.4608 | 0.4114 |
| | | | | | 0.4612 | 0.4134 |
| Example 36 | 15% | 2% | 16.40 | 4.10 | 0.4540 | 0.4080 |
| | | | | | 0.4587 | 0.4107 |
| | | | | | 0.4563 | 0.4104 |
| Example 37 | 15% | 3% | 15.60 | 3.90 | 0.4489 | 0.4073 |
| | | | | | 0.4506 | 0.4054 |
| | | | | | 0.4503 | 0.4063 |
| Example 38 | 15% | 4% | 14.80 | 3.70 | 0.4530 | 0.4068 |
| | | | | | 0.4525 | 0.4103 |
| | | | | | 0.4534 | 0.4123 |
| Example 39 | 15% | 5% | 14.00 | 3.50 | 0.4449 | 0.4014 |
| | | | | | 0.4500 | 0.4105 |
| | | | | | 0.4492 | 0.4088 |
| Example 40 | 15% | 7% | 14.00 | 3.50 | 0.4507 | 0.4111 |
| Comparative | | | 22.95 | 4.05 | 0.4504 | 0.4140 |
| Example 7 | | | | | | |

1.-14. (canceled)

15. An LED encapsulant comprising a scattering particle mixture, which comprises components (i) and (ii):
(i) a linear polymer including a dimethylsiloxane group and/or a linear polymer including a methylphenylsiloxane group and/or a diphenylsiloxane group, the linear polymers having at least one vinyl end substituent; and
(ii) at least one silicone resin of one of structures M^{Vi}D^{H}D^{Ph}T^{Ph}, M^{Vi}M^{H}D^{Ph}T_{Ph}, M^{Vi}D^{H}T^{Ph}, M^{Vi}M^{H}T^{Ph}, or M^{Vi}(D)T^{Ph}
wherein if (i) acts as silicone matrix then (ii) acts as scattering particles and if (ii) acts as silicone matrix then (i) acts as scattering particles.

16. The LED encapsulant comprising a scattering particle mixture of claim 15, wherein at least one of the components is included as scattering particles while another one or more components is included as a silicone matrix.

17. The LED encapsulant of claim 15, further comprising a surfactant having a (CH₃)₂Si—O structure and a (CH₃)PhSi—O structure.

18. The LED encapsulant of claim 17, wherein, when a portion of the surfactant having a (CH₃)₂Si—O structure is defined as A and a portion of the surfactant having a (CH₃)PhSi—O structure is defined as B, the surfactant has an ABA, BAB, or AB structure.

19. The LED encapsulant of claim 15, further comprising a crosslinking agent.

20. The LED encapsulant of claim 15, further comprising a curing inhibitor, a catalyst and a fluorescent substance.

21. The LED encapsulant of claim 15, which further comprises nanoparticles.

22. The LED encapsulant of claim 20, which further comprises at least one particulate selected from the group consisting of TiO₂, ZnO, and silica.

23. The LED encapsulant of claim 22, wherein the sum of the contents of TiO₂, ZnO, and silica particulates is from 0.05 to 5 wt % based on the total weight of scattering particles.

24. The LED encapsulant of claim 23, wherein the average particle size of the TiO₂, ZnO, and silica particulates is between 1 and 50 nm.

25. The LED encapsulant of claim 17, wherein the surfactant comprises at least one compound selected from the group consisting of vinyltrimethoxysilane, methacryloxymethylmethyldimethoxysilane, methacryloxymethyltriethoxysilane, 3-methacryloxypropyltrimethoxysilane, methyltriethoxysilane, allyltriethoxysilane, octyltriethoxysilane and tetraethoxysilane.

26. An LED package comprising:
an LED chip; and
the LED encapsulant of claim 15.

27. The LED package of claim 26, wherein the LED chip emits blue light when current is applied.

28. The LED package of claim 26, which further comprises a yellow fluorescent substance.

29. The LED package of claim 27, which further comprises a yellow fluorescent substance.
